(19) United States
(12) Patent Application Publication
(10) Pub. No.: US 2013/0109133 A1
(43) Pub. Date: May 2, 2013

(54) REAR-POINT-CONTACT PROCESS OR PHOTOVOLTAIC CELLS

(71) Applicants: Michel R. Frei, Palo Alto, CA (US); Hemant P. Mungekar, Campbell, CA (US); Hari K. Ponnekanti, San Jose, CA (US)

(72) Inventors: Michel R. Frei, Palo Alto, CA (US); Hemant P. Mungekar, Campbell, CA (US); Hari K. Ponnekanti, San Jose, CA (US)

(21) Appl. No.: 13/651,221

(22) Filed: Oct. 12, 2012

Related U.S. Application Data
(60) Provisional application No. 61/553,104, filed on Oct. 28, 2011.

(51) Int. Cl. H01L 31/02

(52) U.S. Cl. 438/98; 257/E31.113

(57) ABSTRACT

Embodiments of the invention generally relate to methods for performing rear-point-contact processes on substrates, particularly solar cell substrates. The methods generally include disposing a substrate on a substrate support which functions as a mask during deposition of a passivation layer on a back surface of the substrate. A process gas is introduced to an area between the back surface of the substrate and the substrate support in order to deposit the passivation layer on the back surface of the substrate. The deposited passivation layer has openings therethrough in order to facilitate electrical contact of the substrate with a metallization layer subsequently formed over the passivation layer. The passivation layer is formed without requiring a separate patterning and etching process of the passivation layer.

### CROSS-REFERENCE TO RELATED APPLICATIONS

This application claims benefit of U.S. Provisional Patent Application Ser. No. 61/553,104, filed Oct. 28, 2011, which is herein incorporated by reference.

### BACKGROUND OF THE INVENTION

1. Field of the Invention

Embodiments of the invention generally relate to methods of and apparatus for forming a passivation layer on a back surface of a solar cell.

2. Description of the Related Art

Solar cell efficiency is reduced by a combination of loss mechanisms, including recombination at the front surface of the cell, recombination in the bulk of the cell, and recombination at the back surface of the cell. To improve solar cell efficiency, the front and bulk recombination can be reduced by a combination of process and material improvements, such as selective emitters and high-lifetime silicon. When such improvements are implemented, recombination at the back surface becomes the dominant loss mechanism.

One proposed solution to reduce back surface recombination is the rear-point-contact process, in which a dielectric passivation layer is disposed over a back surface of a solar cell, and then a contact metallization is disposed over the dielectric passivation layer. The dielectric passivation layer has a collection of openings therethrough to allow electrical contact between the solar cell and a metallization disposed over the dielectric passivation layer. The rear-point-contact process generally includes forming a dielectric passivation layer on the back surface of the solar cell, patterning and etching openings through the passivation layer, and then depositing a metallization over the dielectric passivation layer. The rear-point-contact process, while improving the efficiency of the solar cell, adds extra process steps to the solar cell manufacturing process, particularly with respect to the patterning of the passivation layer. Patterning of the passivation layer requires timely alignment of masks, and subsequent etching and cleaning of the solar cells. The extra process steps of the rear-point-contact process increase the cost to manufacture the solar cells and slow production throughput, thus increasing the cost per kilowatt-hour of the solar cells.

Therefore, there is a need for improved methods of and apparatus for performing a rear-point-contact process on solar cells.

### SUMMARY OF THE INVENTION

Embodiments of the invention generally relate to methods and apparatus for performing rear-point-contact processes on substrates, particularly solar cell substrates. The methods generally include disposing a substrate on a substrate support within a chamber. The substrate support has posts which contact the substrate and function as a mask during deposition of a passivation layer on a back surface of the substrate. A process gas is introduced to an area between the back surface of the substrate and the substrate support in order to deposit the passivation layer on the back surface of the substrate. The deposited passivation layer has openings therethrough corresponding to the position of the support posts. The openings facilitate electrical contact between the substrate and a metallization layer subsequently formed over the passivation layer. The passivation layer is formed without a separate patterning and etching process of the passivation layer to form openings therethrough due to the masking performed by the substrate support.

The methods may also generally include disposing a substrate in a chamber on a substrate support having a plurality of apertures therethrough. The apertures control the flow of a process gas to the back surface of a substrate, thus facilitating formation of a passivation layer on the back surface of the substrate. The passivation layer deposited on the back surface of the substrate has areas of relatively greater thickness and areas of relatively less thickness due to the positioning of the apertures and the gas flow therethrough. The passivation layer is then exposed to an etchant to remove passivation material from the areas of relatively less thickness to form openings through the passivation layer. Thus, a passivation layer having openings therethrough is formed without patterning and etching the passivation layer. A conductive material may then be disposed over the passivation layer.

The apparatus generally include substrate supports configured to affect the deposition of material on the back surface of a substrate supported thereon. The substrate supports may include a plurality of support posts which contact the back surface of a substrate supported thereon to mask the deposition of material during a deposition process performed on the back surface of the substrate. Alternatively, substrate supports may include a plurality of gas blocking features and a plurality of apertures therethrough to affect the flow of process gas to the back surface of a substrate. The gas blocking features and the apertures facilitate formation of a passivation layer having a varying thickness on the back surface of the substrate.

In one embodiment, a method of forming a passivation layer on a substrate comprises positioning a substrate on a substrate support. The substrate support includes support posts having terminal ends in contact with a back surface of the substrate. The back surface of the substrate is then exposed to a process gas to deposit a passivation layer on the back surface of the substrate. The terminal ends of the support posts mask the deposition of the passivation layer in some locations to define openings through the passivation layer. The substrate is then removed from the substrate support and a conductive material is deposited on the back surface of the substrate. The conductive material is deposited over the passivation layer and in contact with the substrate at areas of the substrate defined by the openings through the passivation layer.

In another embodiment, a method of forming a passivation layer on a substrate comprises positioning a substrate on a substrate support. The substrate support comprises a plurality of support posts positionable in contact with a back surface of the substrate near the perimeter of the substrate, and a plurality of gas blocking features to block or reduce the flow of a process gas to desired areas of the substrate. The substrate support also includes a plurality of apertures positioned between the plurality of gas blocking features. The substrate is exposed to a process gas to deposit a passivation layer on the back surface of the substrate. Exposing the substrate to the process gas comprises flowing a process gas through the apertures of the substrate support and into contact with the substrate. The gas blocking features and the apertures of the substrate support are positioned to form a passivation layer with areas of first thickness and areas of a second thickness less than the first thickness. The passivation layer is then exposed to an etchant to uniformly reduce the thickness of the passivation layer.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A-1B are schematic sectional views of a chamber and a substrate during a passivation layer formation process according to one embodiment of the invention.

FIG. 2 is a top perspective view of a substrate support according to one embodiment of the invention.

FIG. 3 is a schematic sectional view of a substrate having a passivation layer thereon positioned within a process chamber.

FIG. 4 is a schematic sectional view of a substrate having a passivation layer and a conductive material thereon.

FIGS. 5A-5B are schematic sectional views of a chamber and a substrate during a passivation layer formation process according to another embodiment of the invention.

FIG. 6 is a top perspective view of the substrate support shown in FIGS. 5A and 5B.

FIGS. 7A-7C are schematic sectional views of a substrate during a conductive material formation process according to one embodiment of the invention.

FIG. 8 is schematic sectional view a solar cell formed using a rear-point-contact process according to one embodiment of the invention.

FIG. 9 is a graph illustrating solar cell efficiency versus opening pitch for solar cells having various-sized contact openings.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the invention generally relate to methods and apparatus for performing rear-point-contact processes on substrates, particularly solar cell substrates. The methods generally include disposing a substrate on a substrate support within a chamber. The substrate support has posts which contact the substrate and function as a mask during deposition of a passivation layer on a back surface of the substrate. A process gas is introduced to an area between the back surface of the substrate and the substrate support in order to deposit the passivation layer on the back surface of the substrate. The deposited passivation layer has openings therethrough corresponding to the position of the support posts. The openings facilitate electrical contact between the substrate and a metallization layer subsequently formed over the passivation layer. The passivation layer is formed without a separate patterning and etching process of the passivation layer to form openings therethrough due to the masking performed by the substrate support.

The methods may also generally include disposing a substrate in a chamber on a substrate support having a plurality of apertures therethrough. The apertures control the flow of a process gas to the back surface of a substrate, thus facilitating formation of a passivation layer on the back surface of the substrate. The passivation layer deposited on the back surface of the substrate has areas of relatively greater thickness and areas of relatively less thickness due to the positioning of the apertures and the gas flow therethrough. The passivation layer is then exposed to an etchant to remove passivation material from the areas of relatively less thickness to form openings through the passivation layer. Thus, a passivation layer having openings therethrough is formed without patterning and etching the passivation layer. A conductive material may then be disposed over the passivation layer.

The apparatus generally include substrate supports configured to affect the deposition of material on the back surface of a substrate supported thereon. The substrate supports may include a plurality of support posts which contact the back surface of a substrate supported thereon to mask the deposition of material during a deposition process performed on the back surface of the substrate. Alternatively, substrate supports may include a plurality of gas blocking features and a plurality of apertures therethrough to affect the flow of process gas to the back surface of a substrate. The gas blocking features and the apertures facilitate formation of a passivation layer having a varying thickness on the back surface of the substrate.

Embodiments of the present invention may be practiced in an atomic layer deposition chamber (ALD) or chemical vapor deposition (CVD) chamber, such as those available from Applied Materials, Inc., of Santa Clara, California. It is contemplated that chambers from other manufacturers may also be utilized to practice embodiments of the invention.

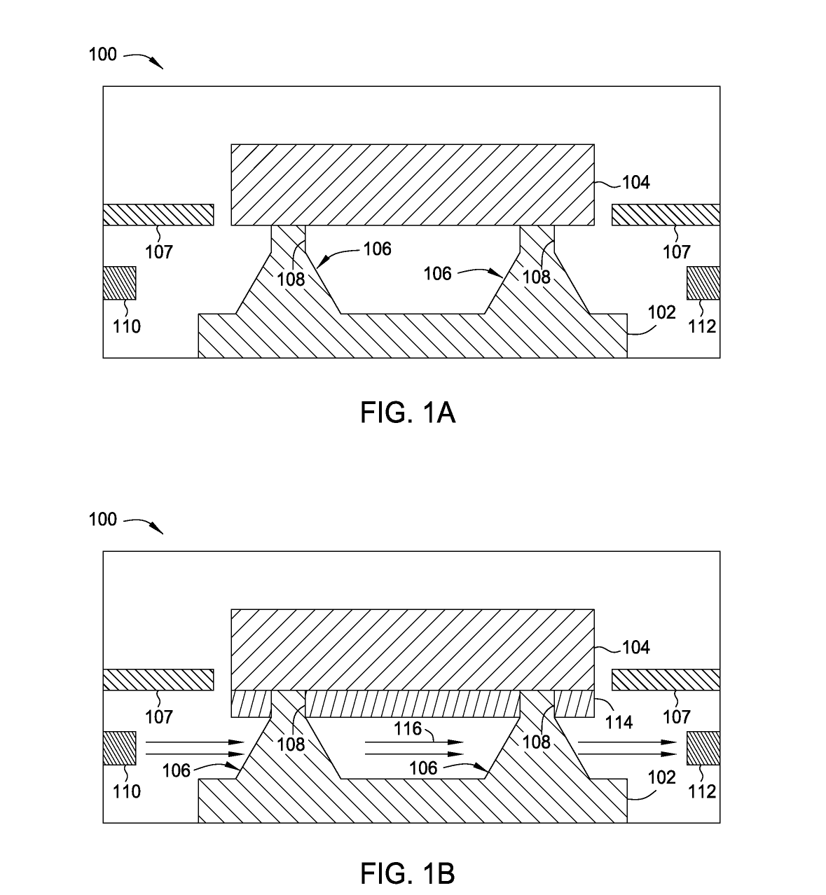

FIGS. 1A-1B are schematic sectional views of a chamber 100 and substrate 104 during a passivation layer formation process according to one embodiment of the invention. A substrate 104, such a crystalline silicon substrate used in the formation of solar cells, is positioned in a chamber 100, such as an ALD or CVD chamber. The chamber 100 has a substrate support 102 disposed therein. The substrate support 102 is formed from silicon carbide and may optionally include a graphite coating thereon.

The substrate support 102 includes plurality of support posts 106 adapted to support the substrate 104 on terminal ends 108 of the support posts 106. The support posts 106 have a conical base with a cylindrical tip; however, other shapes for the support posts 106 are contemplated. The terminal ends 108 are adapted to contact the back surface (e.g., the non-light-receiving surface of a solar cell) of the substrate 104 during processing, such as a deposition process. The terminal ends 108 simultaneously function as both masking features and support structures during deposition processes performed on the substrate 104. The size and spacing of the support posts 106 can be selected to provide adequate support to the substrate 104, as well as to facilitate the formation of a desired pattern during a deposition process on the back surface of the substrate 104. While only two support posts 106 are shown for purposes of clarity, it is contemplated that substrate support 102 may include hundreds or thousands of the support posts 106. In one example, it is contemplated that the substrate support 102 may include about 1000 support posts 106 having a height of about 0.5 millimeters, a cylindrical tip having a diameter of about 200 micrometers, and a spacing therebetween of about 1500 micrometers.

A process gas inlet 110 is disposed laterally outward of the substrate support 102 and is adapted to direct one or more process gases, such as precursor gases, along lines 116 (shown in FIG. 1B) horizontally across the back surface of the substrate 104 to deposit a material thereon. The process gases are exhausted through an exhaust port 112 disposed on the opposite side of the chamber 100 from the process gas inlet 110. A gas ring 107 is disposed circumferentially around the inner surface of chamber 100. The gas ring 107 has an opening centrally-located therethrough to accommodate the substrate 104. The gas ring prevents or reduces processes gases from entering the upper portion of the chamber 100 and undesirably depositing material in the upper portion of the chamber 100. Although the term “ring” is used to describe the gas ring 107, it is to be understood that the gas ring need not have a circular shape. In addition to or as an alternative to the gas ring 107, the pressure within the upper portion of the chamber 100 may be increased, such as by providing an inert gas thereto, in order to create a pressure gradient to contain process gases within the lower part of the chamber 100.

FIG. 1B illustrates the substrate 104 during deposition of a passivation layer 114, such as a silicon nitride layer, on the back surface of the substrate 104. During deposition of the passivation layer 114, process gases are introduced into the chamber 100 through the process gas inlet 110. The process gases are precursor gases for forming the passivation layer 114, and may include one or more of silane, other silicon-containing compounds, ammonia, other nitrogen-containing compounds, oxygen-containing compounds, and reducing gases such hydrogen. The process gases are thermally decomposed or reduced during a chemical vapor deposition or atomic layer deposition process to deposit the passivation layer 114 on the back surface of the substrate 104. Thermally decomposition of the process gases may be facilitated via heating of the substrate support 102 by a resistive heating element, or by heating the substrate 104 such as with lamps. Although the process gases are illustrated as entering the chamber 100 through a single process gas inlet 110, it is contemplated that the process gases may enter through multiple process gas inlets 110, or may flow through independent gas lines to the process gas inlet 110, in order to reduce process gas reactions from occurring in undesired locations.

The passivation layer may be deposited to a thickness of about 5 nanometers to about 300 nanometers on the back surface of the substrate 104. The process gases flow parallel to the back surface of the substrate 104 in a laminar flow. Parallel flow of the process gases, as compared to flowing the processes gas perpendicular to the bottom surface of the substrate 104, reduces the amount of material that undesirably deposits on the support posts 106. Parallel flow of the process gases reduces the amount of process gases which are redirected from the bottom surface of the substrate 104, as occurs more frequently with perpendicular flow to the substrate 104, and therefore, reduces undesirable deposition on the support posts 106. Thus, parallel flow of the process gases extends the time between cleanings reduces chamber downtime. Unreacted process gases, or process gas byproducts, are subsequently removed from the chamber 100 through the exhaust port 112.

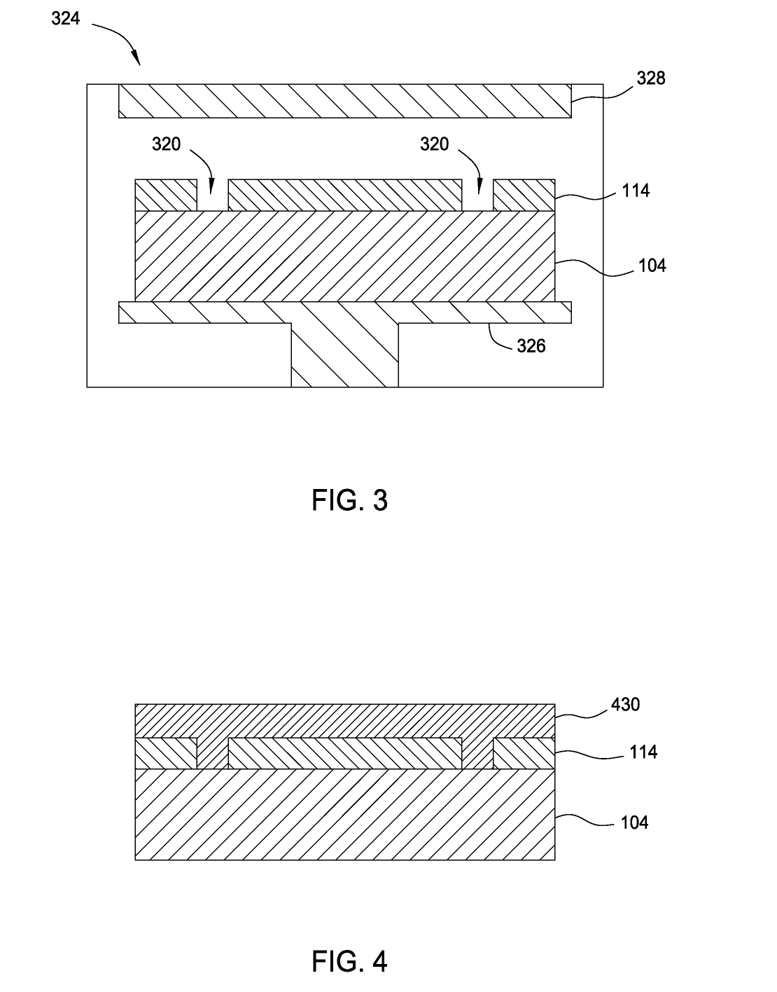

During the deposition of the passivation layer 114, the terminal ends 108 of the substrate support 102 function as both a support for the substrate 104 and as a deposition mask during the deposition of the passivation layer 114. Thus, the passivation layer 114 is formed having openings 320 (shown in FIG. 3) therein. Since openings 320 are formed through the passivation layer 114 during formation of the passivation layer 114, a separate and subsequent patterning and etching of the passivation layer 114 is not required to form the openings 320. Elimination of the subsequent patterning and etching step improves process throughput by reducing processing steps, and reduces production costs by eliminating consumables, such as etchants and cleaning solutions. It is contemplated that the size of the openings 320 may vary slightly due to processing.

In another embodiment, it is contemplated that the process gases may be provided to the back surface of the substrate 104 in a perpendicular direction rather than in a direction parallel to the back surface of the substrate 104. In such an embodiment, gas inlet nozzles may be positioned between the support posts 106 and adapted to direct gas perpendicularly to the back surface of the substrate 104. When introducing process gases to the substrate 104 in this manner, it is contemplated that the substrate support 102 may require more frequent cleaning than when the process gases flow parallel to the back surface of the substrate 104.

In another embodiment, it is contemplated that multiple passivation layers, and not just a single passivation layer 114, may be deposited over the back surface of the substrate 104. For example, a silicon nitride layer and a silicon oxide layer may be stacked on the back surface of the substrate 104. In such an embodiment, it is contemplated that the substrate support 102 may act as a mask for the deposition of both the silicon nitride layer and the silicon oxide layer. It is also contemplated that each of the passivation layers may be deposited in different chambers, and that the substrate 104 may be transferred from a first chamber to a second chamber while positioned on the substrate support 102. In an alternative embodiment utilizing multiple passivation layers, it is contemplated that a first passivation layer may be blanket deposited over the entire back surface of a substrate 104. A second passivation layer having openings 320 therethrough may then be deposited on the first passivation layer utilizing the substrate support 102 described above. Subsequently, the first passivation layer may be selectively etched through the openings 320 of the second passivation layer while using the second passivation layer as mask.

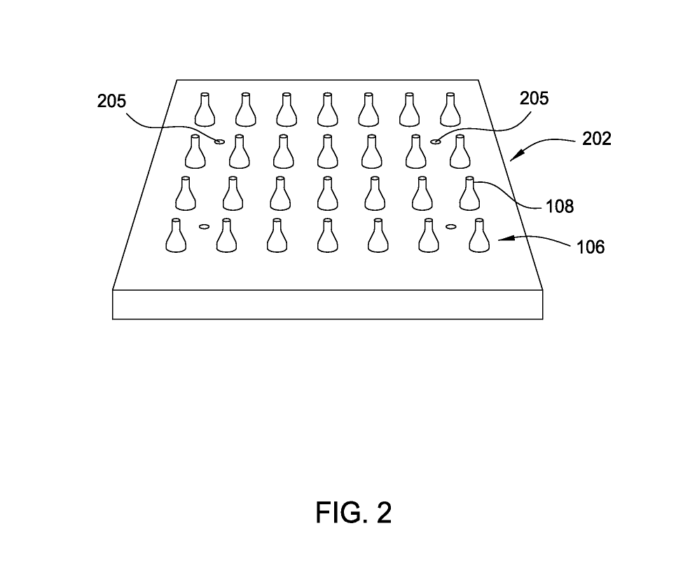

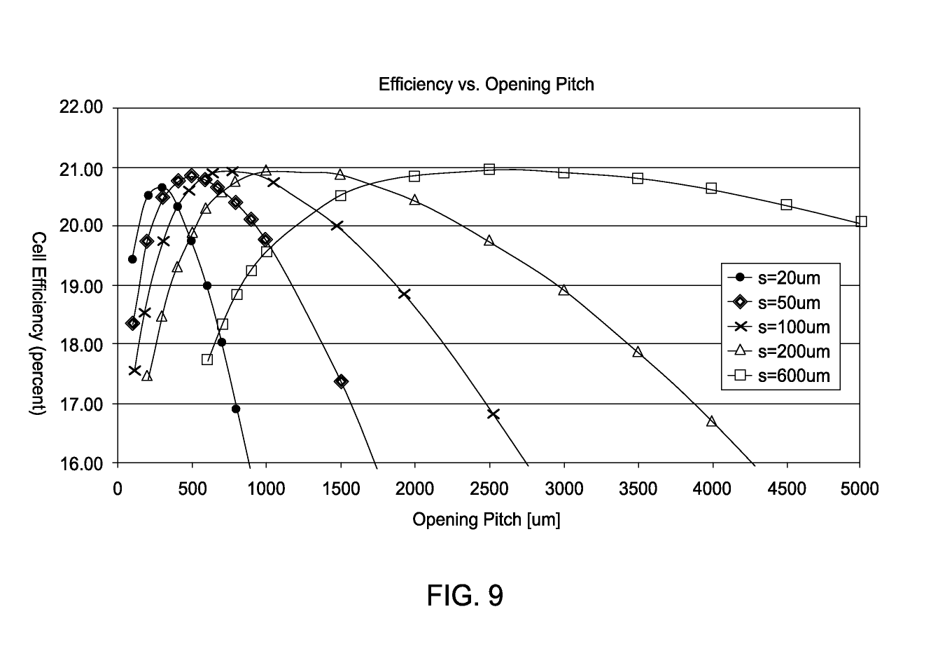

FIG. 2 is a top perspective view of a substrate support 202 according to one embodiment of the invention. The substrate support 202 is similar to the substrate support 102, except the substrate support 202 includes additional support posts 106. The substrate support 202 can be utilized to support a substrate (not shown) on the terminal ends 108 of the plurality of support posts 106 while forming a passivation layer on the back surface of the substrate. The substrate support 202 includes 28 support posts 106 on an upper surface thereof. However, it is contemplated that more or less support posts may be located on an upper surface of the substrate support 202 in order to facilitate the formation of a passivation layer having a desired number of openings therethrough, as explained further with reference to FIG. 9. The upper surface of the substrate support 202 is smoothed or polished to reduce the undesirable deposition of material thereon and flaking of material therefrom.

The substrate support 202 also includes a plurality openings 205 to accommodate lift pins (not shown). The lift pins are disposed through the openings 205 and are engaged by an actuator positioned beneath the substrate support 202. Actuation of the lifts pins by the actuator raises and lowers a substrate supported thereon away or towards the plurality of support posts 106 to facilitate positioning of a substrate on the support posts 106. With the lift pins in an elevated position, a robot positions a substrate on the lifts pins which are then lowered to dispose a substrate on the supports posts 106. A substrate can be removed from the substrate support 202 in a reverse process.

FIG. 2 illustrates one embodiment of a substrate support 202; however, other embodiments are also contemplated. In another embodiment, it is contemplated that the substrate support 202 may have a circular shape, and may be adapted to support a circular substrate, such as a silicon wafer, thereon. In yet another embodiment, it is contemplated that the substrate support 202 may lack support posts 106. Instead, the substrate support 202 may include another structure, such as elevated lines, a grid pattern, or an egg-crate pattern for supporting a substrate thereon. In such an embodiment, the substrate support 202 would be utilized to deposit a passivation layer having openings therethrough corresponding to the respective pattern. In another embodiment, it is contemplated that the substrate support 202 may also act as a carrier, and may be transferable between process chambers with a substrate positioned thereon.

FIG. 3 illustrates the substrate 104 positioned in a chamber 324 after formation of the passivation layer 114 on the substrate 104. Prior to positioning the substrate 104 in the chamber 324, such as a physical vapor deposition (PVD) chamber, the substrate 104 is removed from the chamber 100 by a robot (not shown) having end effectors which are accommodated by lift pins. The robot lifts the substrate 104 from the lift pins and removes the substrate 104 from the chamber 100. The substrate 104 is then positioned in the chamber 324. The chamber 324 includes a substrate support 326 on which the substrate 104 is positioned via the robot utilized to remove the substrate 104 from the chamber 100. The substrate 104 is positioned with the passivation layer 114 oriented towards a target material 328 which is to be sputtered onto the substrate 104. A power source (not shown), such as an RF or DC power source, is coupled to the chamber 324 to facilitate sputtering of the target material 328 onto the substrate 104. In another embodiment, it is contemplated that the chamber 324 shown in FIG. 3 may be a CVD chamber, an electroplating chamber, or a screen printing apparatus, rather than a PVD chamber.

FIG. 4 is a sectional view of a substrate 104 having a passivation layer 114 and a conductive material 430 disposed thereon. The conductive material 430 may be formed on the substrate 104 in a chamber, such as the chamber 324 illustrated in FIG. 3, for example by sputtering, CVD, electroplating, or screen printing. The conductive material 430 is disposed over the passivation layer 114 and within the openings 320 in electrical contact with the substrate 104. The conductive material 430 is a metal, such as silver or aluminum, and functions as a contact structure for electrically connecting the substrate 104 to a busbar or other current collection assembly when assembled into a photovoltaic module. Thus, the substrate 104 illustrated in FIG. 4 includes a conductive material 430 in electrical contact therewith and a passivation layer 114 on a back surface thereof, and is formed without the extraneous process steps of patterning and etching the passivation layer 114 prior to deposition of the conductive material 430.

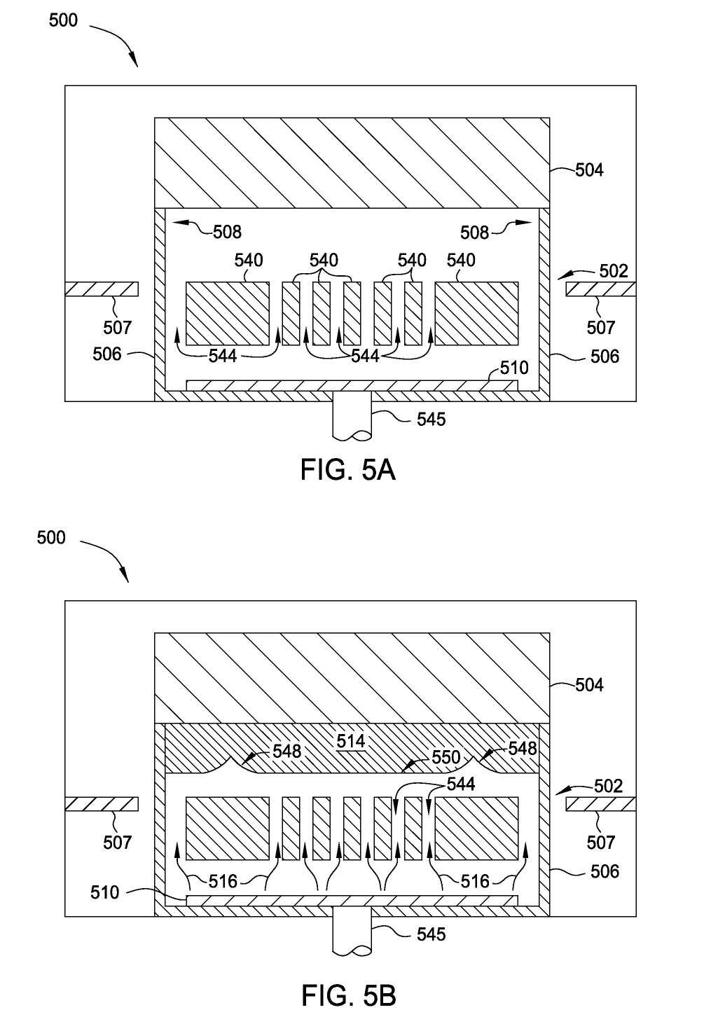

FIGS. 5A-5B are schematic sectional views of a chamber 500 and a substrate 504 during a passivation layer formation process according to another embodiment of the invention. FIG. 5A illustrates a substrate 504, such as a crystalline silicon substrate used to form solar cells, positioned in a chamber 500, such as an ALD or CVD chamber. The chamber 500 has a substrate support 502 disposed therein. The substrate support 502 includes support posts 506 adapted to support the substrate 504 on the terminal ends 508 of the support posts 506. The terminal ends 508 are adapted to contact the back surface (e.g., the non-light-receiving surface) of the substrate 504 during processing, such as a deposition process. The support posts 506 are positioned on the outer edge of the substrate support 502 and are adapted to contact points along the outer perimeter of the substrate 504 to support the substrate 504. Although only two support posts 506 are shown in FIG. 5A, it is contemplated that any number of support posts 506 can be utilized to support the substrate 504.

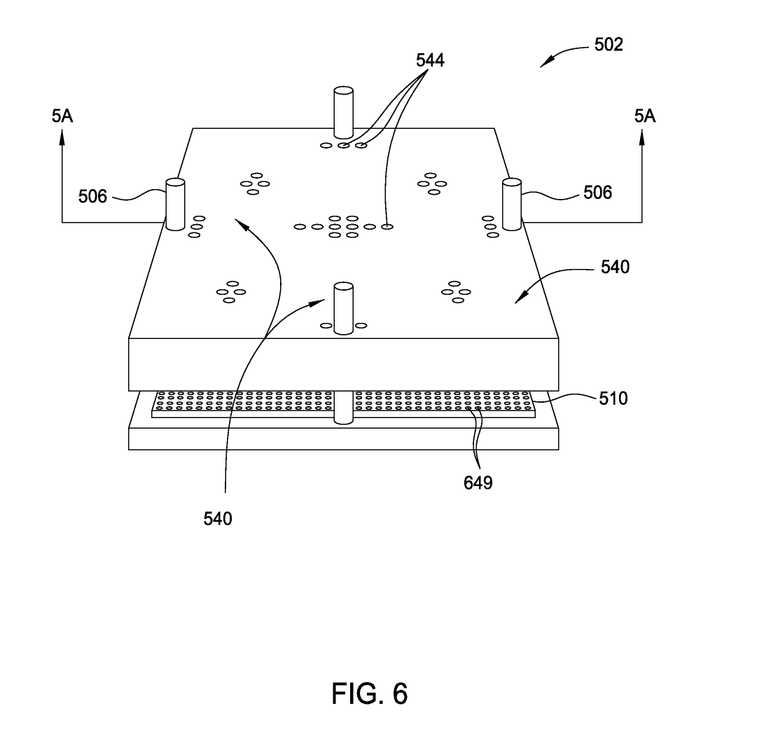

The substrate support 502 also includes gas blocking features 540 disposed laterally inward of the support posts 506 and above a gas inlet 510, such as a diffuser plate. In the embodiment shown in FIG. 5A, the gas inlet 510 is coupled to the substrate support 502 by the support posts 506. The gas blocking features 540 reduce the flow of process gases near select locations of the back surface of the substrate 504 to reduce deposition of passivation material on the substrate at areas adjacent the gas blocking features. A plurality of apertures 544 are disposed between the gas blocking features 540 of the substrate support 502 in order to allow the process gases to flow therethrough to contact the substrate 504. The sizing and the spacing of the apertures 544 may be adjusted to effect the desired amount of gas flow therethrough, as explained in more detail with reference to FIG. 5B and FIG. 9. A top perspective view of the substrate support 502 is shown in FIG. 6 to further illustrate the substrate support 502. A gas ring 507, which is similar to gas ring 107, is disposed around the periphery of the substrate support 502 to contain process gases to the lower part of the chamber 500.

FIG. 5B illustrates the substrate 504 during formation of a passivation layer 514 on the back surface thereof. The passivation layer 514 is formed by flowing process gases along lines 516 into the chamber 500 through a gas inlet 510. The gas inlet 510 is adapted to receive processes gases from a gas supply line 545 and deliver the process gases to the back surface of the substrate 504. The process gases flow into the chamber 500 through the gas inlet 510 and then through the apertures 544 towards the back surface of the substrate 504. The process gases react or are thermally decomposed to deposit a passivation layer on the substrate 504. Thermally decomposition of the process gases may be facilitated via heating of the substrate support 502 by a resistive heating element, or by heating the substrate 504 such as with lamps.

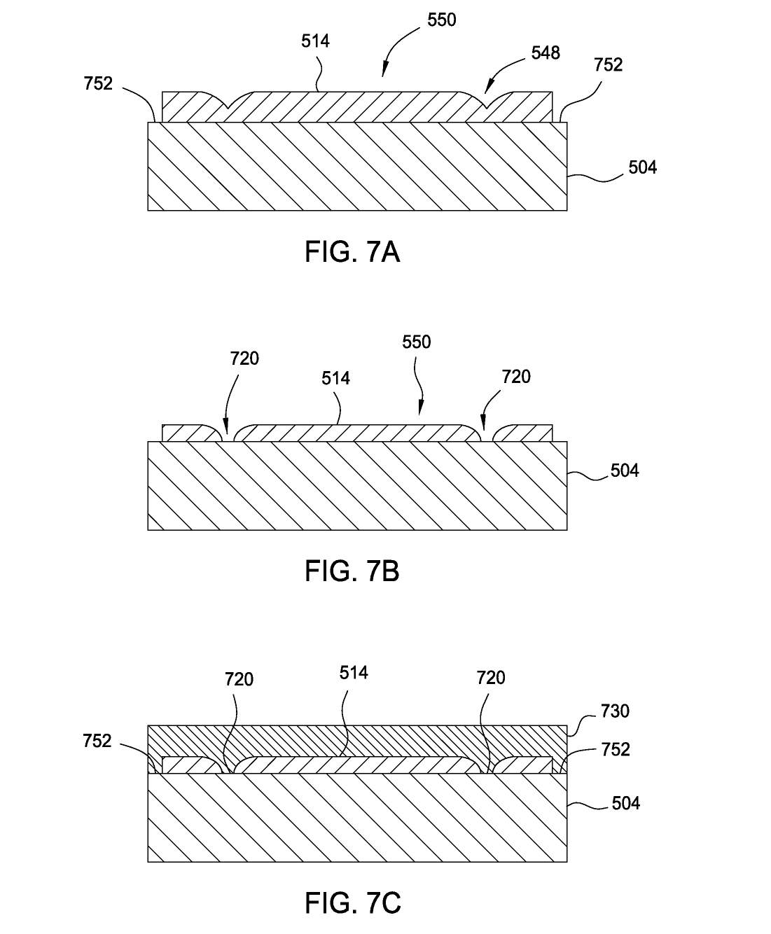

The gas blocking features 540 are positioned to reduce the flow of the process gases near desired areas of reduced deposition thickness in order to form areas 548. Areas 550 are located adjacent to the areas 548 and have a thickness greater than areas 548, such as about twice as great. The areas 548 having a relatively lesser thickness correspond to subsequently formed openings 520 (shown in FIG. 7B). The formation of the areas 548 is facilitated by the gas blocking features 540, which reduce the amount of process gases contacting the back surface of the substrate 504 in desired areas (e.g., the areas 548). Similarly, the formation of the areas 550 having a relatively greater thickness is facilitated by the placement of the apertures 544, which allow increased flow of the process gases to desired areas of the back surface of the substrate 504. Thus, the location of the areas 548 having a relatively lesser thickness and the locations of areas 550 having a relatively greater thickness is dependent upon the position on the apertures 544 and the gas blocking features 540.

FIG. 6 is a top perspective view of the substrate support 502 shown in FIGS. 5A and 5B. The substrate support 502 includes apertures 544 surrounded by gas blocking features 540. In the embodiment illustrated in FIG. 6, a plate of material has apertures 544 formed therethrough, and the remaining material of the plate surrounding the apertures 544 functions as the gas blocking features 540. Four support posts 506 are spaced at 90 degree increments around the perimeter of the substrate support 502 to support a substrate thereon. It is contemplated that the size, spacing, and density of apertures 544 can be adjusted to affect the deposition of material on a substrate 504, as desired. Thus, the size, density, and number of contact points formed on a substrate through a passivation layer can be controlled by varying the position and amount of the apertures 544. In the embodiment shown in FIG. 6, the substrate support 502 is adapted to form a passivation layer with nine areas of relatively less thickness. However, it is contemplated that more or less areas of relatively less deposition thickness may be formed depending on substrate size, amount of electric current generated, or other process specifications. In one example, it is contemplated that the substrate support 502 may contain a sufficient number of apertures 544 and gas blocking features 540 to form a passivation layer 514 having about 1000 openings therethrough, with each opening having a diameter of about 300 micrometers.

As illustrated in FIG. 6, the gas inlet 510 includes a plate having a plurality of apertures 649 formed therein to allow process gases to flow therethrough. In an alternative embodiment, it is contemplated that a wall or frame (not shown) may be disposed around the gas inlet 510 and coupled to the plate through which the apertures 544 are formed, thus containing process gases therein and reducing undesired deposition of material on chamber components within the chamber. In yet another embodiment, it is contemplated that the substrate support 502 may have a round perimeter, rather than a square or rectangular perimeter, and thus may be suitably adapted to process circular substrates such as silicon wafers. In yet another embodiment, it is contemplated that the apertures 544 may be positioned to form a linear or grid-shaped opening through the passivation layer 514. In another embodiment, it is contemplated that the substrate support 502 may also act as a carrier, and may be transferable between process chambers with a substrate positioned thereon.

FIGS. 7A-7C are schematic sectional views of a substrate 504 during formation of a conductive material thereon according to one embodiment of the invention. FIG. 7A illustrates the substrate 504 having the passivation layer 514 formed thereon. The passivation layer 514 may be formed in a chamber, such as chamber 500 shown in FIGS. 5A and 5B. The passivation layer 514 generally covers the entire back surface of the substrate 504, except at points 752 where the support posts 506 of the substrate support 502 (shown in FIGS. 5A and 5B) contact the substrate 504 during deposition of the passivation layer 514.

FIG. 7B illustrates the substrate 504 after exposing the passivation layer 514 to an etchant, for example a wet etchant such as potassium hydroxide (KOH) or phosphoric acid. It is contemplated that dry etching may also be utilized. Exposure of the passivation layer 514 to an etchant uniformly removes a portion of the passivation layer 514 (e.g., removes a uniform thickness of material). For example, about 25 percent to about 50 percent of the thickness of the passivation layer 514 may be removed. As illustrated in FIG. 7B, the substrate 504 has been exposed to the etchant for a sufficient period of time to remove passivation material located at areas 548 of the passivation layer 514. Removal of the passivation material from the areas 548 results in the formation of openings 720 which expose the back surface of the substrate 504 through the passivation layer 514. Since the passivation layer 514 is uniformly etched by an etchant, passivation material is also removed from the increased deposition areas 550. It is generally desirable to leave enough passivation material after etching in the increased deposition areas 550 to sufficiently passivate the substrate 504. After etching the passivation layer 514, a conductive material 730 may be applied to the back surface of the substrate 504 over the passivation layer 514 and in electrical contact with the substrate 504 to facilitate removal of electric current from the substrate 504.

FIG. 7C illustrates the substrate 504 after etching of the passivation layer 514 and deposition of a conductive material 730 thereon. The conductive material 730 is deposited using a chamber, such as chamber 324 illustrated in FIG. 3. The conductive material 730 is deposited over the passivation layer 514 and in the openings 720 in order to facilitate electric contact between the substrate 504 and a current collection grid or busbar in a photovoltaic array (not shown). The conductive material 730 is in contact with the back surface of the substrate 504 in the openings 720 due to the removal of passivation material from areas 548, as well as at the points 752 due to the masking of the substrate 504 by the support posts 506 (shown in FIGS. 5A and 5B) during deposition of the passivation layer 514. Thus, the substrate 504 illustrated in FIG. 7C includes conductive material 730 and a passivation layer 514 formed without a separate patterning and etching process of the passivation layer 514. Although the passivation layer 514 was etched, the etching process is blanket etch which does not require alignment of a mask or deposition of a masking material on the substrate 504. Since alignment of a mask and deposition of a masking material are not necessary, the amount of process steps to form a device on the substrate 504 is reduced, and process throughput is increased as compared to processes which require a separate masking and etching process of the passivation layer 514.

FIGS. 7A and 7B illustrate one embodiment of forming a passivation layer 514 having openings 720 therethrough; however, other embodiments are also contemplated. In another embodiment, it is contemplated that the passivation layer 514 may be deposited on the substrate 504 to a uniform thickness. In such an embodiment, the composition of the passivation layer 514 varies at different locations of the passivation layer 514 to facilitate selective etching at desired locations of the passivation layer 514. The composition of the passivation layer 514 can be controlled by utilizing the apertures and the gas blocking features 540 of the substrate support 502 to deliver desired process gases to predetermined regions of the substrate 504. For example, when depositing a silicon nitride layer, it is contemplated that a nitrogen-containing precursor may have a greater flow rate near one region of the substrate 504 as compared to another region of the substrate 504, thereby depositing a film having a higher nitrogen concentration in some areas. The areas with a relatively greater nitrogen concentration may be etched more slowly than areas with relatively less nitrogen concentration, depending on the etchant used, thereby facilitating selective etching and removal of the deposited material in desired locations. By controlling the delivery of process gases to areas of the substrate 504, the composition of the passivation layer 514 can be controlled, thus facilitating selective etching of the passivation layer to form openings 720 therethrough.

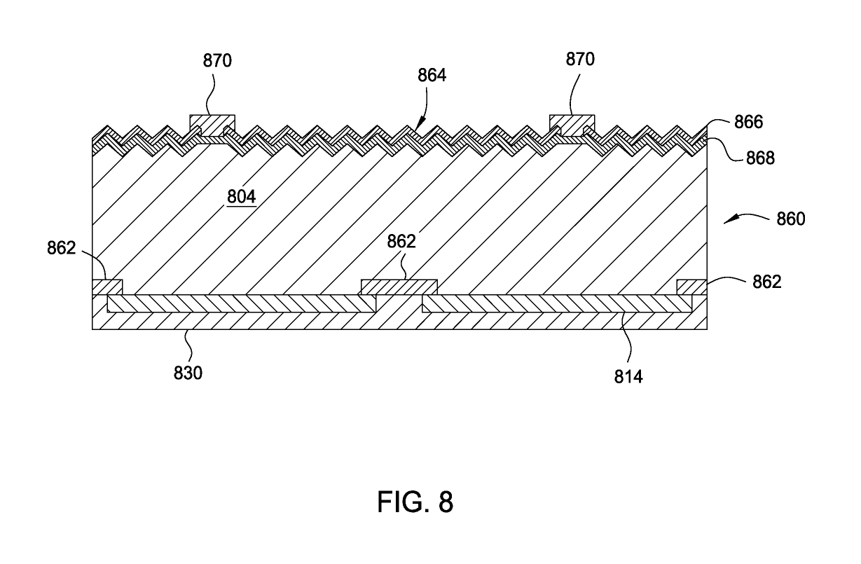

FIG. 8 is schematic sectional view a solar cell 860 formed using a rear-point-contact process according to one embodiment of the invention. The solar cell 860 includes a substrate 804, such as a p-type silicon substrate, having a passivation layer 814 and conductive material 830 disposed on a back surface thereof. The substrate 804 is similar to or may be the same as the substrates 104 and 504. The passivation layer 814 is similar to passivation layers 114 and 514 described above, and may be formed in the same manner as passivation layers 114 and 514. The conductive material 830 is in electrical contact with p-type emitter regions 862 on the back surface of the substrate 804. The p-type emitter regions 862 are doped regions on the back surface of the substrate 804 which facilitate electrical connection between the substrate 804 and the conductive material 830. The p-type emitter regions 862 are formed by exposing the substrate to a p-type dopant, such as boron.

The solar cell 860 also includes a textured surface 864 on the light-receiving surface (e.g., the front surface) of the solar cell 860. The textured surface 864 reduces the amount of incident light reflected from the light-receiving surface of the solar cell 860 in order to increase the efficiency of the solar cell 860. The textured surface 864 also includes an anti-reflective coating (ARC) 866 to further reduce the reflection of incident light. An n-type emitter layer 868 is disposed on the upper surface of the substrate 804 adjacent to the ARC 866. The n-type emitter layer 868 is in electrical contact with the front contacts 870, which facilitate extraction of electrical current form the solar cell 860.

FIG. 9 is a graph illustrating solar cell efficiency versus opening pitch (e.g., center-to-center spacing of openings) for solar cells having various-sized openings through a passivation layer on a back surface thereof. Passivation layers having more or larger openings therethrough allow for more conductive material to be in contact with the substrate through the openings. The increased surface area of conductive material in contact with the substrate facilitates increased electrical conductivity of electrical current. However, the increased amount or size of the openings reduces the amount of passivation material on the back surface of the substrate, which increases recombination at the back surface of the substrate. Thus, the amount, sizing, and spacing of openings through the passivation layer both negatively and positively affect the efficiency of the solar cell. FIG. 9 illustrates the effect of opening pitch for different size openings. FIG. 9 plots the cell efficiency for five passivation layers having different size openings therethrough: 20 micrometers (μm), 50 μm, 100 μm, 500 μm, and 600 μm. As illustrated in FIG. 9, the pitch between the openings and the size of the openings can be adjusted to maximize the efficiency of the solar cell regardless of the opening size. In the examples illustrated in FIG. 9, the maximum solar cell efficiency is about 21 percent. Thus, for each chosen pitch and opening size, there is an optimal solar cell efficiency that can be obtained.

Benefits of the present invention include methods and apparatus to form solar cells using a reduced number of process operations. Specifically, solar cells can be formed using a rear-point-contact process which does not require a separate patterning and etching process of a passivation layer after deposition of the passivation layer on the back surface of a substrate. Since an additional patterning and etching process is not required, processing throughput is increased.

While the foregoing is directed to embodiments of the present invention, other and further embodiments of the invention may be devised without departing from the basic scope thereof, and the scope thereof is determined by the claims that follow.

1. A method of forming a passivation layer on a substrate, comprising:
positioning a substrate on a substrate support, the substrate support including support posts having terminal ends in contact with a back surface of the substrate;
exposing the back surface of the substrate to a process gas to deposit a passivation layer on the back surface of the substrate, wherein the terminal ends of the support posts mask the deposition of the passivation layer to define openings through the passivation layer;
removing the substrate from the substrate support; and
depositing a conductive material on the back surface of the substrate over the passivation layer and in contact with the substrate at areas of the substrate defined by the openings through the passivation layer.

2. The method of claim 1, wherein exposing the back surface of the substrate to the process gas comprises flowing the process gas parallel to the back surface of the substrate.

3. The method of claim 1, wherein exposing the back surface of the substrate to the process gas comprises flowing the process gas perpendicular to the back surface of the substrate.

4. The method of claim 1, wherein the passivation layer is deposited by atomic layer deposition or chemical vapor deposition.

5. The method of claim 1, wherein the passivation layer comprises silicon nitride.

6. The method of claim 5, wherein the passivation layer is deposited to a thickness of about 5 nanometers to about 300 nanometers.

7. The method of claim 6, wherein the passivation layer is deposited by atomic layer deposition or chemical vapor deposition.

8. A method of forming a passivation layer on a substrate, comprising:
positioning a substrate on a substrate support, the substrate support comprising:
a plurality of support posts, the support posts in contact with a back surface of the substrate near the perimeter of the substrate;
a plurality of gas blocking features; and
a plurality of apertures positioned between the plurality of gas blocking features;
exposing the substrate to a process gas to deposit a passivation layer on the back surface of the substrate, the exposing comprising flowing a process gas through the apertures of the substrate support and into contact with the substrate, wherein the gas blocking features and the apertures of the substrate support are positioned to form the passivation layer having areas of a first thickness and areas of a second thickness less than the first thickness; and
exposing the passivation layer to an etchant to uniformly reduce the thickness of the passivation layer.

9. The method of claim 8, wherein exposing the substrate comprises depositing a passivation layer over the entire back surface of the substrate except for at points in contact with the support posts of the substrate support.

10. The method of claim 8, wherein exposing the passivation layer to an etchant comprises removing a sufficient amount of the passivation layer to expose the back surface of the substrate at the areas of the second thickness.

11. The method of claim 10, further comprising depositing a conductive material over the passivation layer.

12. The method of claim 11, wherein the etchant is a wet etchant.

13. The method of claim 12, wherein the etchant is potassium hydroxide.

14. The method of claim 8, wherein the passivation layer is formed by chemical vapor deposition or atomic layer deposition.

15. The method of claim 8, wherein the process gas is flown substantially perpendicular to the bottom surface of the substrate while depositing the passivation layer.

16. The method of claim 8, wherein the etchant is a wet etchant.

17. The method of claim 16, wherein exposing the substrate comprises depositing a passivation layer over the entire back surface of the substrate except for at points in contact with the support posts of the substrate support.

18. The method of claim 17, wherein the passivation layer is formed by chemical vapor deposition or atomic layer deposition.

19. The method of claim 18, wherein the passivation layer is deposited to a thickness of about 100 nanometers to about 300 nanometers.

20. The method of claim 19, wherein the passivation layer comprises silicon nitride.
